(19) United States
(12) Patent Application Publication
(10) Pub. No.: US 2006/0045968 A1
(43) Pub. Date: Mar. 2, 2006

(54) Atomic layer deposition of high quality high-k transition metal and rare earth oxides

(76) Inventors: Matthew V. Metz, Hillsboro, OR (US); Mark R. Brazier, Manning, OR (US); Timothy E. Glassman, Portland, OR (US); Christopher D. Thomas, Aloha, OR (US); Lawrence J. Foley, Hillsboro, OR (US); Christopher G. Parker, Hillsboro, OR (US); Ying Zhou, Tigard, OR (US); Markus Kuhn, Portland, OR (US); Suman Datta, Beaverton, OR (US); Jack Kavalieros, Portland, OR (US); Mark L. Doczy, Beaverton, OR (US); Justin K. Brask, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 10/925,573

(22) Filed: Aug. 25, 2004

(51) Int. Cl. C23C 16/00

(52) U.S. Cl. 427/248.1

(57) ABSTRACT

Increasing the number of successive pulses of oxidant before applying pulses of metal precursor may improve the quality of the resulting metal or rare earth oxide films. These metal or rare earth oxide films may be utilized for high dielectric constant gate dielectrics. In addition, pulsing the oxidant during the pre-stabilization period may be advantageous. Also, using more pulses of oxidant than the pulses of precursor may reduce chlorine concentration in the resulting films.

### BACKGROUND

This invention relates generally to the deposition of transition metal and rare earth oxides.

Transition metal and rare earth oxides may be deposited as gate oxides for metal gate field effect transistor integrated circuits. Conventional atomic layer deposition of transition metal and rare earth oxide may be disadvantageous. One problem with some existing processes is that the chlorine concentration in the resulting film may be high. Chlorine can lead to degradation of the dielectric constant and may promote reactions with the gate electrode, degrading device performance and decreasing reliability. The inclusion of chlorine into the dielectric lattice may result in the formation of oxygen vacancies, which may degrade the effectiveness of the gate oxide.

Thus, there is a need for better ways to form high dielectric constant transition metal and rare earth oxides, for example, for forming gate dielectrics for metal gate electrode semiconductors.

### BRIEF DESCRIPTION OF THE DRAWINGS

FIG. 1 is a schematic depiction of an atomic layer deposition chamber in accordance with one embodiment of the present invention; and

FIG. 2 is a depiction of a process sequence in accordance with one embodiment of the present invention.

### DETAILED DESCRIPTION

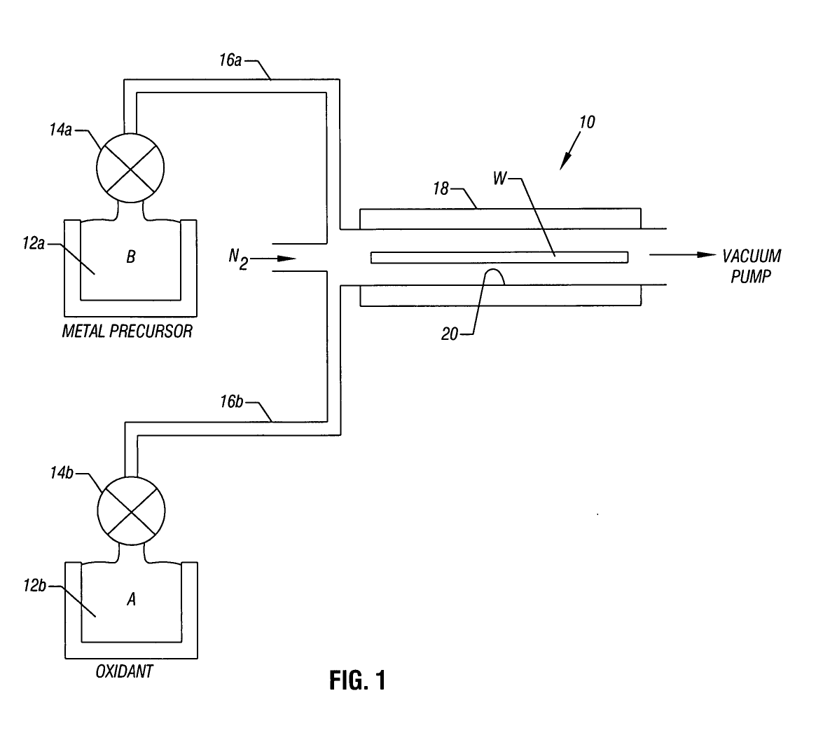

Referring to FIG. 1, an atomic layer deposition device 10 may include a chamber 20 having heaters 18 surrounding the chamber. A wafer W to be exposed to production gases may be inserted within the chamber 20. In one embodiment of the present invention, nitrogen gas (N₂) may continuously flow through the chamber 20 to a vacuum pump.

A first precursor A may be contained in liquid form within a closed, pressurized, heated reservoir 12b. The injection of the precursor A, as a gas, into the chamber 20 via the line 16b may be controlled by a high speed valve 14b. In one embodiment of the present invention, the reservoir 12b holds an oxidant such as water, hydrogen peroxide, or ozone.

A metal precursor may be stored in a closed, pressurized, heated reservoir 12a. The metal precursor may, for example, be hafnium chloride (HfCl₄) in connection with forming a hafnium oxide metal dielectric film. Other metal precursors include any of the transition metal and rare earth oxides including those suitable for forming high dielectric constant gate oxides such as hafnium oxide, hafnium silicon oxide, lanthanum oxide, lanthanum aluminum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate. As used herein, a high dielectric constant oxide is one with a dielectric constant of at least ten. The reservoir 12a communicates with the chamber 20 via line 16a, whose flow is controlled by a high speed valve 14a.

Due to the presence of the high speed valves 14a and 14b, pulses of metal precursor or oxidant may be supplied to the chamber 20 in any desired sequence.

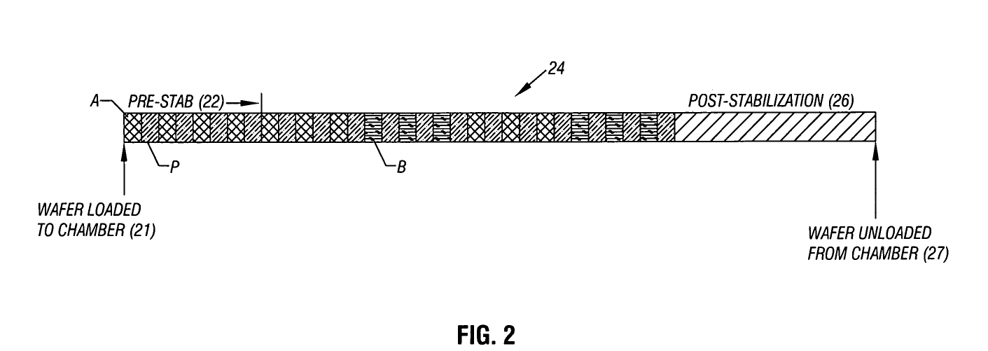

Referring to FIG. 2, in accordance with one embodiment of the present invention, the formation of metal oxide films may be accomplished using a first pre-stabilization stage 22, followed by a film deposition stage 24, in turn followed by a post-stabilization stage 26. In some embodiments of the present invention, the pre-stabilization stage 22 may be shortened relative to conventional techniques. In some embodiments, the pre-stabilization time at temperature may even be minimized before deposition begins, to maximize surface hydroxyl termination for the first cycles of dielectric film deposition.

During the pre-stabilization stage 22, the wafer W is loaded into the chamber 20, as indicated at 21. A pulse of oxidant (A) may be followed by a short purge cycle (P). This oxidant/purge sequence may be repeated four or more times in some embodiments. During the pre-stabilization stage, the wafer W is being heated and the chamber 20 is being prepared for film deposition. In one embodiment, the pre-stabilization stage may use water as the oxidant. Thus, a purge cycle may follow each oxidant pulse. Providing the oxidant during the pre-stabilization stage may increase surface hydroxyl termination for early stages of film growth in some embodiments.

After the pre-stabilization stage 22, a series of pulses of the oxidant A may each be followed by a purge. Thus, in the illustrated embodiment, three pulses of oxidant A, followed by three purges, are implemented. However, the repeat of times one is subject to great variability. In some embodiments of the present invention, it is desirable to have two times the number of pulses of the oxidant relative to the number of pulses of the metal precursor. Increasing the number of oxidant pulses may reduce the chlorine concentration in the resulting metal oxide film. The pulse width may be selectable in accordance with conventional procedures.

After a series of pulses of the oxidant, a series of pulses of the metal precursor B, each followed by a purge, may be implemented. In some embodiments, the number of pulses of oxidant may be higher than the number of pulses of the metal precursor. The number of pulses of the metal precursor may be determined by the desired film thickness. By pulsing the same precursor multiple times in succession, layer-to-layer reactions can be pushed further towards completion, resulting in films closer to ideal composition, with fewer defects, leading to higher performance gate dielectrics in some embodiments.

For example, in connection with hafnium chloride as the metal precursor, providing two water pulses for each hafnium chloride pulse may decrease the chlorine concentration in the resulting hafnium oxide films by two to three times.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
providing at least two pulses of an oxidant before providing a pulse of a metal precursor to an atomic layer deposition chamber to form a metal or rare earth oxide film.

2. The method of claim 1 including heating said chamber during a prestabilization period.

3. The method of claim 2 including providing a pulse of oxidant followed by a purge during the prestabilization period.

4. The method of claim 3 including providing a plurality of pulses of oxidant during the prestabilization period.

5. The method of claim 1 including providing a plurality of pulses of oxidant each followed by a purge before providing the metal precursor to the deposition chamber.

6. The method of claim 5 including providing a plurality of pulses of metal precursor each followed by a purge.

7. The method of claim 6 including providing a series of pulses of oxidant after providing said pulses of precursor.

8. The method of claim 7 including following each pulse of oxidant after the precursor pulses with a purge.

9. The method of claim 1 including providing more pulses of oxidant than pulses of precursor.

10. The method of claim 1 including providing a metal precursor to form a metal or rare earth oxide having a dielectric constant greater than ten.

11. A method comprising:
forming a layer of a rare earth or metal oxide film in a deposition chamber using more pulses of an oxidant than pulses of a metal precursor.

12. The method of claim 11 including providing at least two pulses of oxidant before providing a pulse of a metal precursor.

13. The method of claim 11 including heating said chamber during a prestabilization period.

14. The method of claim 13 including providing a pulse of oxidant followed by a purge during the prestabilization period.

15. The method of claim 14 including a plurality of pulses of oxidant during the prestabilization period.

16. The method of claim 11 including providing a plurality of pulses of oxidant, each followed by a purge before providing the metal precursor to the deposition chamber.

17. The method of claim 16 including providing a plurality of pulses of a metal precursor each followed by a purge.

18. The method of claim 17 including providing a series of pulses of oxidant after providing said pulses of precursor.

19. The method of claim 18 including following each pulse of oxidant after the precursor pulses with a purge.

20. The method of claim 11 including providing a metal precursor to form an oxide having a dielectric constant greater than ten.

21. A method comprising:
introducing oxidant during the prestabilization period between wafer introduction into a deposition chamber and the beginning of deposition.

22. The method of claim 21 including heating said chamber during a prestabilization period.

23. The method of claim 22 including providing a pulse of oxidant followed by a purge during the prestabilization period.

24. The method of claim 23 including providing a plurality of pulses of oxidant during the prestabilization period.

25. The method of claim 21 including providing a plurality of pulses of oxidant each followed by a purge before providing the metal precursor to the deposition chamber.

26. The method of claim 25 including providing a plurality of pulses of metal precursor each followed by a purge.

27. The method of claim 26 including providing a series of pulses of oxidant after providing said pulses of precursor.

28. The method of claim 27 including following each pulse of oxidant after the precursor pulses with a purge.

29. The method of claim 21 including providing more pulses of oxidant than pulses of precursor.

30. The method of claim 21 including providing a metal precursor to form a metal or rare earth oxide having a dielectric constant greater than ten.
